(19) United States
(12) Patent Application Publication
(10) Pub. No.: US 2008/0105295 A1
(43) Pub. Date: May 8, 2008

(54) METHOD FOR STRUCTURING OF A THIN-LAYER SOLAR MODULE

(76) Inventor: Dieter MANZ, Schlaitdorf (DE)

Correspondence Address: Striker, Striker & Stenby, 103 East Neck Road, Huntington, NY, 11743, US

(21) Appl. No.: 11/933,750

(22) Filed: Nov. 1, 2007

(30) Foreign Application Priority Data
Nov. 2, 2006 (DE) 10 2006 051 555.2

(51) Int. Cl. H01L 31/04; B05D 1/00; B05D 3/06

(52) U.S. Cl. 136/252; 427/554; 427/74

(57) ABSTRACT

For structuring of a thin-layered solar module a plurality of thin layers are deposited onto a substrate, linear tracks are introduced in each case into the thin layers, in which linear tracks the material of at least one thin layer is removed again, before or during the introduction of a new track, the course of an existing track is determined, and the course of the new track is regulated relative to the course of the existing track during the introduction of the new track. Thin-layer solar modules with improved efficiency can thus be produced.

### CROSS-REFERENCE TO A RELATED APPLICATION

The invention described and claimed hereinbelow is also described in German Patent Application DE 10 2006 051 555.2 filed on Nov. 2, 2006. This German Patent Application, whose subject matter is incorporated here by reference, provides the basis for a claim of priority of invention under 35 U.S.C. 119(a)-(d).

### BACKGROUND OF THE INVENTION

The invention relates to a method for the structuring of a thin-layer solar module, wherein a plurality of thin layers are deposited onto a substrate, and wherein linear tracks are introduced in each case into the thin layers, in which linear tracks the material of at least one thin layer is removed again.

Thin-layer solar modules comprise a substrate and typically three thin layers deposited thereon. The thin-layer solar modules are divided into structural units, which are separated from one another by transition zones. The separation of electrons and holes takes place in the structural units in the presence of irradiation with light (i.e. the actual conversion of light into electrical energy), whilst the electrical wiring and contacting of the structural units takes place with the transition zones.

To this end, tracks (or troughs) are required in the transition zones, in which tracks material of a thin layer is removed and, if appropriate, is replaced by another material, for example the material of a layer lying above or a conductor, for example silver. A plurality of tracks in a specific sequence lie beside one another (set of tracks) in the transition zones. The tracks lying beside one another must not intersect, because otherwise electrical short-circuits can occur which would make one or more structural units unusable.

In the production of a thin-layer solar module, a first thin layer is usually first deposited over the whole area on a planar substrate and then structured. Here, structuring means the introduction of linear tracks (or troughs) into the layer, i.e. the material in the track is removed. The linear tracks run straight when this introduction takes place. For the structuring, use can for example be made of a mechanical cutter bit or a laser. A second thin layer is then deposited over the whole area onto the first layer, the existing track also being filled with the material of the new layer. A further structuring now takes place, i.e. new linear tracks are introduced. These new tracks again have a straight course when the introduction takes place. A third thin layer is then deposited over the whole area and again structured with straight-running tracks. These last tracks are usually filled with a silver paste. Finally, a heat treatment of the thin-layer solar module usually also takes place.

The substrate is heated during each deposition of a thin layer. The substrate is permanently deformed as a result of this heating. If structurings are already present on the substrate, previously straight-running tracks become distorted on account of this deformation, as a rule arc-shaped. In order to ensure that tracks newly to be introduced do not overlap or even intersect already existing tracks on account of such a distortion, safety distances of approx. 100-200 μm are adhered to between the nominal positions of the tracks.

The safety distances between the tracks widen the area of the transition zones and thus reduce the area of the thin-layer solar module that is available for the photoelectrically active structural units. The efficiency of thin-layer solar modules is thus limited.

### SUMMARY OF THE INVENTION

Accordingly, it is an object of the present invention to make available a method for the structuring of thin-layer solar modules, with which thin-layer solar modules with improved efficiency can be produced.

In keeping with these objects and with others which will become apparent hereinafter, one feature of the present invention resides, briefly stated, in that the course of an existing track is determined before or during the introduction of a new track, and that the course of the new track relative to the course of the existing track is regulated during the introduction of the new track.

The method according to the invention enables an active compensation of the distortion of the substrate and thus of the curvature of already existing tracks due to the heating during the deposition of upper layers. A new track is typically introduced with a curved (non-straight) course, which corresponds to the course of an already existing, adjacent track in the same transition zone.

The safety distance between the tracks of the different layer deposition generations provided in the prior art must be selected in such a way that the distance between adjacent tracks is sufficient from the electrical standpoint also at the narrowest point. A much greater spacing is present however over a large part of the extent of a transition zone, so that an unnecessary area of the thin-layer solar module is wasted.

In contrast with this, it is possible with the aid of the invention to space adjacent tracks only as closely as is necessary electrically (e.g. for insulation reasons) over the whole transition zone. An additional safety distance in order to avoid intersections is not necessary, as a result of which the area of the thin-layer solar module can be used to a greater extent for the light-electrical conversion.

In a preferred variant of the method according to the invention, the course of the new track is regulated in such a way that a constant distance is adjusted between the existing track and the new track. A parallel course of neighbouring tracks in a set of tracks in a transition zone thus results. The constant distance is selected according to the electrical requirements (e.g. the required insulation between the thin layers). Optimum efficiency of the thin-layer solar module is thus achieved.

In another, preferred variant of the method, the course of the existing track is determined as an orthogonal deviation with respect to a straight-running main structuring direction. This makes the determination of the course of the existing track particularly straightforward and facilitates the parallel tracking through the application point of a structuring device.

Particularly preferred is a variant of the method wherein the determination of the course of the existing track takes place optically. Use can be made of both reflection and transmission properties of the substrate and already deposited thin layers. The optical measurement can take place both from the underside of the substrate as well as from the coated upper side of the substrate. The optical determination is particularly cost-effective.

The substrate can be illuminated with one or more light sources. LEDs or lasers, for example, come into consideration as light sources. In particular, a plurality of lasers can be used for the track detection. Provision can be made such that two measurement points are used, at which one measurement point is detected in each case at the edge of a previously introduced track. Alternatively, it is possible to detect a plurality of measurement points, whereby one of the measurement points should lie inside the track. One or more detectors can be used for the track detection. The detectors can enable a uni- or multi-dimensional detection. For example, uni- or multi-dimensional arrays or CCD chips can be used. If a uni-dimensional detector is used, provision can be made such that the latter is rotatable, in order to be able to detect a track also in another direction.

It is particularly preferable if a confocal image is generated and depth information of the existing track or the track currently being introduced is detected from the confocal image. In particular, intensity fluctuations can be detected and regulated to a predetermined intensity.

The direction of movement can be ascertained from the detection of the beam formation. Furthermore, it is possible to detect and evaluate a power gradient. It is also possible to ascertain from the confocal image whether the substrate is corrugated. In this case, refocusing of the laser that is introducing a track can be carried out if need be.

Furthermore, it is conceivable to detect the reflection of the structuring laser. In this way, it is possible to detect the position at which a track is currently being introduced. In particular, a track detection can take place and the position of the tool (the laser) can be determined with the same detector. It is thus possible to detect the introduced track simultaneously with a previously introduced track. The spacing of the tracks can thus be ascertained. A quality control is thus possible. Moreover, the spacing can possibly be corrected.

The tracking of the previously introduced track preferably takes place in a non-scanning manner. This means that no scanning takes place at right angles of the track transverse direction. Tracking in the track transverse direction only possibly takes place on account of an adjustment. A scanning detection of an already introduced track can possibly take place at the starting point, in order to be able actually to locate the previously introduced track. The tracking, however, takes place in a non-scanning manner.

The signals detected by a track position sensor can be processed and/or fed directly as analog signals to a control of a structuring tool, in particular a laser. The analog signals can, furthermore, be fed to hardware and then be processed by software.

If the analog signals are fed directly to the control of the laser, a particularly rapid correction or adjustment of the laser can take place.

An advantageous development of this variant of the method makes provision such that an illumination of the thin-layer solar module takes place with a differing wavelength, the wavelength being adapted to the properties, in particular the transmission and reflection properties, of the materials of the thin layers and, as the case may be, the substrate penetrated by radiation and/or irradiated. By selecting a suitable wavelength, a track in a deeper-lying layer can easily be detected optically. The wavelength is selected in such a way that layers lying farther upwards (i.e. closer to the sensor) can be penetrated by radiation (i.e. a layer lying farther upwards is transparent for the wavelength), but a difference in absorption or reflection is present between the materials which meet one another at the edge of a track to be detected. The wavelength is changed suitably for the detection of tracks of different layer deposition generations, for example by exchanging the light source and if need be the detector.

Preference is also given to a variant of the method according to the invention, wherein the course of the existing track is determined with a track position sensor, the track position sensor being followed up according to the determined course of the existing track. The position of the track position sensor can be used here to control the application point of a structuring device. Moreover, the track position sensor retains a constantly good view of the existing track to be detected. It should be noted that the track position sensor and the structuring device can be disposed on the same side of the substrate or on opposite sides.

In an advantageous development of this variant of the method, provision is made such that an application point of the structuring device, with which the removal of material from at least one thin layer takes place for the introduction of the new track, follows the track position sensor at a defined distance. This simplifies the control of the material removal which takes place at the application point. In the case of mechanical material removal, the application point is the position of the abrasive tool; in the case of material removal by means of laser vaporisation, the application point is the region of the thin layer illuminated by the laser.

In a preferred variant of the method, the introduction of the linear tracks takes place by means of a mechanical cutter bit. The mechanical material removal is particularly cost-effective.

In a likewise preferred, alternative variant of the method, the introduction of the linear tracks takes place by means of a laser beam, whereby, in particular, the laser beam is directed with at least one deflection mirror onto a desired position on the thin-layer solar module. The material removal by means of the laser is particularly precise. By means of the deflection mirror, mechanical movements during the material removal can be reduced to a minimum, namely the deflection mirror or mirrors. The deflection mirror or mirrors are preferably aligned by means of piezoelements. The wavelength of the laser is selected such that an absorption (and therefore a material removal) takes place only in the desired thin layer or layers.

Also falling within the scope of the present invention is a thin-layer solar module produced according to an inventive method described above or one of its variants. The thin-layer solar module according to the invention can achieve a much higher energy yield per unit area than conventional thin-layer solar modules.

An embodiment is preferred in which the thin-layer solar module comprises a plurality of structural units, which are separated from one another by transition zones with in each case a set of linear tracks, the linear tracks of a set running parallel to one another. Optimum efficiency can be achieved with the parallel-running tracks in a transition zone.

A preferred development of this embodiment makes provision such that the adjacent tracks of a set have a spacing of 60 μm or less, measured in the plane of the substrate.

Further features and advantages of the invention emerge from the following detailed description of an example of embodiment of the invention with the aid of the figures in the drawing, which shows details essential to the invention, as well as from the claims. In variants of the invention, the individual features can each be implemented individually by themselves or as a plurality in any combinations.

### BRIEF DESCRIPTION OF THE DRAWINGS

FIG. 1a shows a schematic cross-sectional detail of a partially completed thin-layer solar module according to the invention after the deposition of a first thin layer and its structuring;

FIG. 1b shows a schematic plan view of a part of the thin-layer solar module from FIG. 1a;

FIG. 2a shows the thin-layer solar module according to FIG. 1a after the deposition of a second thin layer;

FIG. 2b shows a schematic plan view of a part of the thin-layer solar module from FIG. 2a;

FIG. 3a shows the thin-layer solar module according to FIG. 2a after a structuring according to the invention;

FIG. 3b shows a schematic plan view of a part of the thin-layer solar module from FIG. 3a;

FIG. 3c shows a schematic plan view of a part of the thin-layer solar module from FIG. 2a during the structuring of the second thin layer;

FIG. 4a shows the thin-layer solar module from FIG. 3a after the deposition of a third thin layer;

FIG. 4b shows a schematic plan view of a part of the thin-layer solar module from FIG. 4a;

FIG. 5a shows the thin-layer solar module from FIG. 4a after a structuring according to the invention;

FIG. 5b shows a schematic plan view of a part of the thin-layer solar module from FIG. 5a;

FIG. 6a shows a schematic plan view of a substrate before a heat treatment;

FIG. 6b shows a schematic plan view of the substrate from FIG. 6a after a heat treatment.

### DESCRIPTION OF THE PREFERRED EMBODIMENTS

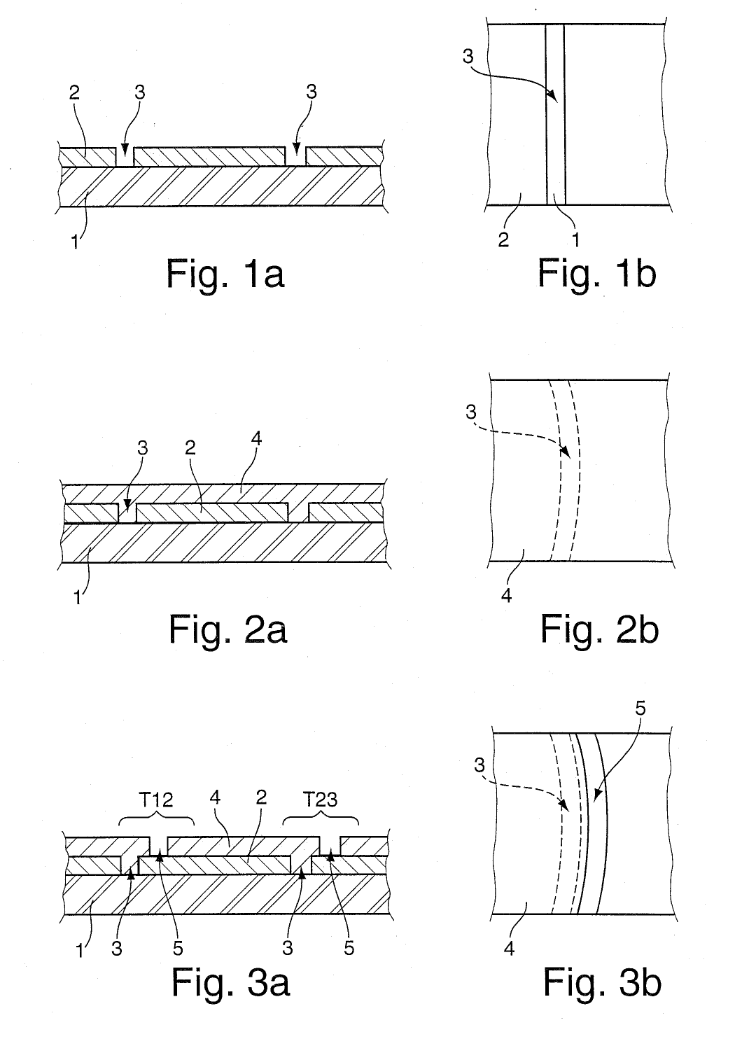

FIGS. 1a to 5b illustrate the course of the production of a thin-layer solar module within the scope of the present invention.

FIGS. 1a and 1b show in each case in cross-section and in plan view a substrate 1, which is typically made of glass (or also metal or plastic), on which a first thin layer 2 is deposited. The process is explained below with the aid of a layer structure of a possible amorphous silicon thin-layer module. This first thin layer 2 is as a rule a TCO (transparent conductive oxide) layer. This layer has already been structured with straight-running tracks 3. For the purpose of simplification, only one of the tracks is shown in FIG. 1b.

A further thin layer 4 is deposited on this first layer 2, as can be seen in FIGS. 2a and 2b. The partially completed thin-layer solar module is heated, whereby substrate 1 can typically become permanently deformed. As a result, existing tracks 3 become deformed and then assume (shown here by way of example) an arc-shaped course (see FIG. 2b). The second thin layer is as a rule a silicon layer. Regarding the distortion of substrate 1, see also FIGS. 6a, 6b.

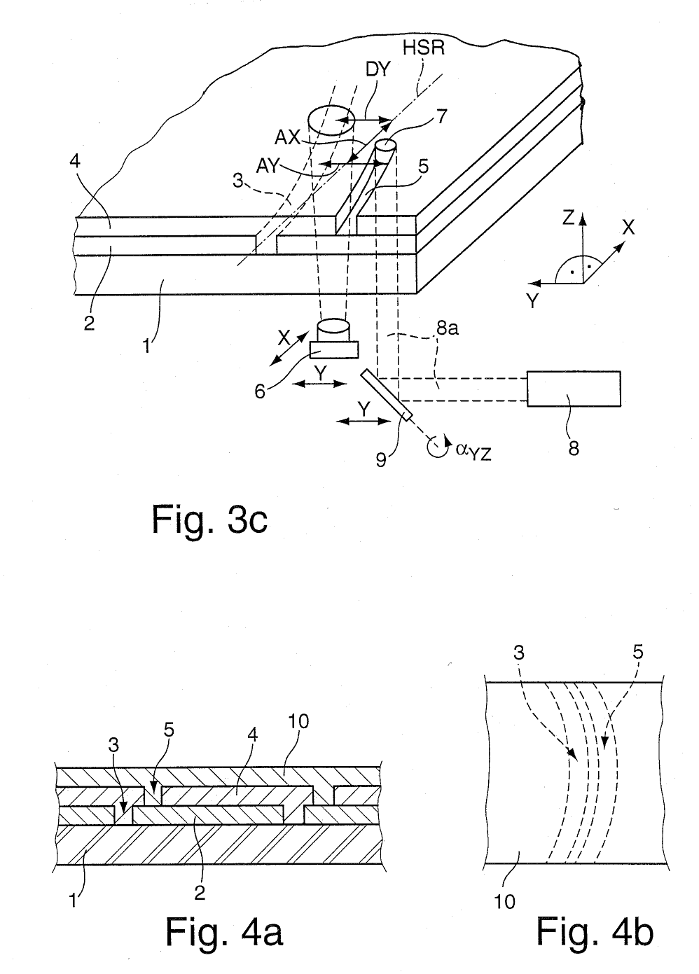

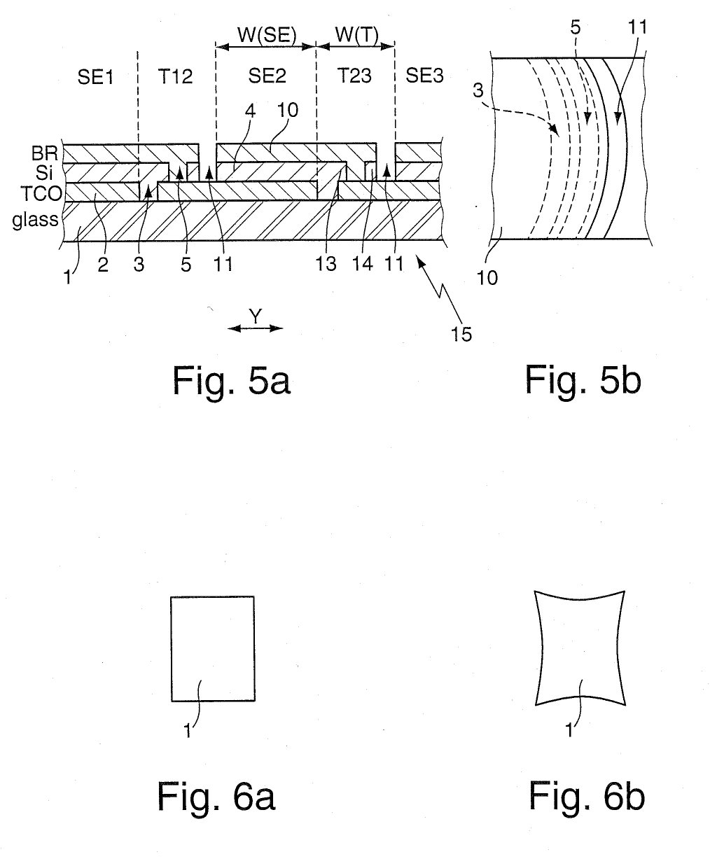

Second thin layer 4 is now structured, see FIGS. 3a to 3b. In second thin layer 4, the material of second layer 4 is removed in a plurality of new tracks 5, for example by means of a laser beam. The course of each new track 5 is orientated in each case to the course of an already existing track 3, whereby respective existing track 3 preferably originates from the same set of tracks, i.e. from the same transition zone, as new track 5 to be introduced. Two transition zones T12 and T23 are shown by way of example in FIG. 3a (see also in this regard FIG. 5a).

The introduction of new tracks 5 into second thin layer 4 is explained in greater detail with the aid of FIG. 3c. For the purpose of simplification, only one transition zone is shown in FIG. 3c, and the spacing of tracks 3, 5 is represented exaggerated.

Track position sensor 6 detects the course of existing track 3 in first thin layer 2. Track 3 is illuminated with a wavelength for which substrate 1 is transparent and which on the other hand makes a contrast between the materials of first and second layer 2, 4 at the edges of track 3 detectable from beneath. Track position sensor 6 registers the course of existing track 3 as a deviation DY in a y-direction at right angles to a straight main structuring direction HSR (which runs parallel to the x-direction). Track position sensor 6 is traversed beneath existing track 3. In practice, track position sensor 6 can be advanced in each case by a small distance Δx in the x-direction (main structuring direction), and the position of track 3 is then measured in the y-direction. If track position sensor 6 detects a relative deviation DY to track 3, it can be traversed in the y-direction in such a way that the position of sensor 6 again lies beneath (in the z-direction) existing track 3. Track position sensor 6 can be orientated and positioned for example at or with one of the edges of existing track 3. Track position sensor 6 can be traversed via suitable guides (not shown) in the x- and y-direction.

The course of existing track 3 is known through the positions in the y-direction of track position sensor 6 in the course of its advance in the x-direction. Parallel to existing track 3, an application point 7 traces a new track 5 parallel to existing track 3. Application point 7 is the region in which a material removal (in this case on second thin layer 4) takes place. Application point 7 is generated by a structuring device. The structuring device comprises here a laser 8, whose light beam 8a is directed by means of a deflection mirror 9 towards application point 7. In the present case, laser beam 8a penetrates both substrate 1 and first thin layer 2 and is not absorbed until second thin layer 4, as a result of which heating and vaporisation of material of thin layer 4 occurs. Application point 7 runs after track position sensor 6 in the x-direction at a fixed distance AX, whereby a fixed distance AY in the y-direction, related to the previous position of track position sensor 6 during the current x-position of application point 7, is adhered to. Application point 7 is directed by the tilting and traversing of deflection mirror 9, for example photoelectrically with translation in the y-direction and tilting α_{yz} about an axis parallel to the yz-angle bisector.

Within the scope of the present invention, all new tracks are in principle produced with the aid of an orientation to existing tracks. It should be noted that a plurality of new tracks can also be produced simultaneously.

As an alternative to a track position sensor, a photographic picture in each case of a larger part of the partially completed thin-layer solar module is conceivable, whereby these photographs are then used as a map in each case for the traversing of the application point (not shown).

The further procedure with the production of thin-layer solar modules is shown in FIGS. 4a and 4b. A third thin layer 2 is deposited over the full area on structured second thin layer 4. Third thin layer 10 is as a rule a metallic layer. During the deposition of third layer 10, substrate 1 may be deformed again, e.g. by introduced heat during the coating process. Existing tracks 3, 5 from different layer deposition generations are however affected to the same extent.

A further structuring follows, i.e. new tracks 11 are in turn introduced into third thin layer 10 and here also into second thin layer 4, see FIGS. 5a, 5b. According to the invention, the course of new tracks 11 is orientated to the course of existing tracks 3, 5 preferably of the same set of tracks, i.e. same transition zone T12, T23. Since existing tracks 3, 5 of a set run parallel to one another, both track 3 and track 5 can be used as orientation during the introduction of a new track 11. As a result, tracks 3, 5, 11 of a set of tracks run parallel to one another.

FIG. 5a shows the structure of a thin-layer solar module 15 according to the invention comprising structural units SE1, SE2, SE3 and transition zones T12, T23. The generation of electrical energy in the presence of light irradiation takes place in structural units SE1, SE2, SE3, whilst transition zones T12, T23 are used for the electrical connection of the structural units and are not photoelectrically active. Within the scope of invention, it is possible to limit its insulation zones 13, 14 between tracks 3, 5, 11 (i.e. the spacing of the tracks) to the electrically essential, minimum width (in the y-direction). The ratio of the widths of the structural units W(SE) to the widths of the transition zones W(T), i.e. W(SE)/W(T), can thus be increased. This increases the efficiency of thin-layer solar module 15. Typical widths of tracks 3, 5, 11 amount in each case to approx. 40-50 μm, and the width of the structural units typically amounts in each case to approx. 3-12 mm, a large number (>10) of structural units being disposed beside one another on a thin-layer solar module. With the aid of the invention, the width of insulation zones 13, 14 can be reduced to a constant approx. 5-20 μm in each case, whereas in the prior art widths of the insulation zones or safety distances of in each case 40-200 μm have to be adhered to.

It should be noted that, within the scope of the invention, axial errors of processing machines can also be compensated for during the introduction of structures (e.g. first track 3).

In addition, FIGS. 6a and 6b show in plan view a whole substrate 1, such as is used for a thin-layer solar module, in FIG. 6a before and in FIG. 6b after heating, such as takes place during a deposition of a thin layer. After the heating, substrate 1 is typically distorted in a pillow-like manner; this distortion also remains in place after cooling. As a result, structures and tracks which have already been applied to substrate 1 also become distorted. The farther outward (i.e. from the centre of substrate 1) the structure or track lies, the greater the distortion.

In the figures, the distortions due to heating are not represented to scale, but are exaggerated.

It will be understood that each of the elements described above, or two or more together, may also find a useful application in other types of constructions differing from the type described above.

While the invention has been illustrated and described as embodied in a method for the structuring of a thin-layer solar module, it is not intended to be limited to the details shown, since various modifications and structural changes may be made without departing in any way from the spirit of the present invention.

Without further analysis, the foregoing will so fully reveal the gist of the present invention that others can, be applying current knowledge, readily adapt it for various applications without omitting features that, from the standpoint of prior art, fairly constitute essential characteristics of the generic or specific aspects of this invention.

What is claimed as new and desired to be protected by Letters Patent is set forth in the appended claims:

1. A method of structuring of a thin-layer solar module, comprising the steps of depositing a plurality of thin layers on a substrate; introducing linear tracks into said thin layers, in which linear tracks a material of at least one thin layer is removed again; and before or during the introduction of a new track, determining a course of an existing track in that a course of the new track is regulated relative to the course of the existing track during the introduction so as to regulate a course of the new track relative to the course of the existing track during the introduction of the new track.

2. A method as defined in claim 1, wherein said regulating includes regulating the course of the new track in such a way that a constant distance is adjusted between the existing track and the new track.

3. A method as defined in claim 1, wherein said determining the course of the existing tracks includes determining the course of the existing track as an orthogonal deviation relative to a straight-running main structuring direction.

4. A method as defined in claim 1, wherein said determining the course of the existing track includes determining of the course of the existing track optically.

5. A method as defined in claim 4, wherein said determining the course of the existing track optically includes illuminating the thin-layer solar module with a defined wavelength adapted to properties, in particular transmission and reflection properties, of the materials of the thin layers; and acting on the substrate in a way selected from the group consisting of penetrating by radiation, irradiating, and both.

6. A method as defined in claim 1, wherein said determining the course of the existing track includes determining the course of the existing track with a track position sensor being followed up according to the course of the existing track.

7. A method as defined in claim 6; and further comprising following the track position sensor at a defined distance by an application point of a structuring device, with which the removal of material from at least one thin layer takes place for the introduction of the new track.

8. A method as defined in claim 1, wherein said introduction of the linear tracks includes an introduction of the linear tracks by a mechanical cutter bit.

9. A method as defined in claim 1, wherein said introduction of the linear tracks includes an introduction of the linear tracks by a laser beam, in particular, the laser beam directed with at least one deflection mirror onto a desired position on the thin-layer solar module.

10. A thin-layer solar module, produced by a method comprising the steps of depositing a plurality of thin layers on a substrate, introducing linear tracks into said thin layers, in which linear tracks a material of at least one thin layer is removed again, and before or during the introduction of a new track, determining a course of an existing track in that a course of the new track is regulated relative to the course of the existing track during the introduction so as to regulate a course of the new track relative to the course of the existing track during the introduction of the new track.

11. A thin-layer solar module as defined in claim 10, wherein the thin-layer solar module comprises a plurality of structural units which are separated from one another by transition zones with in each case a set of the linear tracks, with the linear tracks of a set running parallel to one another.

12. A thin-layer solar module as defined in claim 11, wherein adjacent ones of said tracks of a set have a spacing of 60 μm or less, measured in a plane of the substrate.
